(19) United States
(12) Patent Application Publication
(10) Pub. No.: US 2017/0271460 A1
(43) Pub. Date: Sep. 21, 2017

(54) SEMICONDUCTOR DEVICE FOR ULTRA-HIGH VOLTAGE OPERATION AND METHOD FOR FORMING THE SAME

(71) Applicant: NATIONAL CHIAO TUNG UNIVERSITY, Hsinchu City (TW)

(72) Inventors: Chun-Yen CHANG, Hsinchu City (TW); Chun-Hu CHENG, Tainan City (TW); Yu-Pin LAN, Yilan County (TW)

(21) Appl. No.: 15/146,871

(22) Filed: May 4, 2016

(30) Foreign Application Priority Data
Mar. 18, 2016 (TW) 105108498

(51) Int. Cl. H01L 29/40; H01L 29/66; H01L 29/778; H01L 29/423; H01L 29/20; H01L 29/205

(52) U.S. Cl. CPC H01L 29/408; H01L 29/2003; H01L 29/205; H01L 29/7787; H01L 29/4236; H01L 29/66462

(57) ABSTRACT

A semiconductor device for ultra-high voltage (UHV) operation disclosed in the present invention includes a substrate having a normally-on channel, a negative capacitance material layer, an electrode, a source and a drain. The negative capacitance material layer is disposed over the substrate and capable of adjusting the threshold voltage of the semiconductor device so as to transform the normally-on channel into a normally-off channel and change the transistor characteristics of the semiconductor device from a depletion mode to an enhance mode. In addition, the semiconductor device also includes a gate dielectric layer made of high-k material between the negative capacitance material layer, a gate layer between the gate dielectric layer and the negative capacitance material layer and an ion implantation layer in the substrate under the gate. Furthermore, the aforementioned technical features or structures can be formed in a semiconductor device having a gate-recessed structure.

### RELATED APPLICATIONS

This application claims priority to Taiwan Application Serial Number 105108498, filed Mar. 18, 2016, which is herein incorporated by reference.

### BACKGROUND

### Field of Invention

The present invention relates to a semiconductor device and a method for fanning the same. More particularly, the present invention relates to a semiconductor device for ultra-high voltage operation and a method for forming the same.

### Description of Related Art

In semiconductor technologies, semiconductor compounds can be used in forming various types of integrated circuit (IC) devices such as high-efficiency field-effect transistor, high-frequency transistor or high electron mobility transistor (HEMT). The III-V semiconductor compounds are promising in replacing traditional silicon transistors. Among a number of III-V semiconductor compounds, GaN and Ga₂O₃ are potential semiconductor materials, and the wide band gap characteristics they have can provide better resistance to breakdown electric field. Furthermore, GaN substrate or Ga₂O₃ substrate has potential in large-area manufacturing, and the low electric resistances thereof can provide larger electric current.

However, when the III-V semiconductor compounds are GaN or Ga₂O₃, channel will be normally-on, namely, the operation mode of a semiconductor device is depletion mode (D-mode). In other words, the circuit between a source and a drain is normally-on even without applying voltage on a gate, which causes waste of electricity or interference between circuits. Nowadays, solutions to solve the problems, such as thinning down thickness of GaN or Ga₂O₃ layer, still cannot be satisfactory in various aspects. Therefore, improvements in this field are needed.

### SUMMARY

To solve the aforementioned problems, the present disclosure provides a semiconductor device for ultra-high voltage operation and a method for forming the same.

In accordance with some embodiments of the present disclosure, a semiconductor device for ultra-high voltage operation is provided. The semiconductor device includes a substrate having a normally-on channel, a negative capacitance material layer, a gate, a drain, and a source, wherein the negative capacitance layer is disposed on the substrate, the gate is disposed on the negative capacitance material layer, and the drain and the source are disposed on opposite of the gate and are electrically connected to the normally-on channel.

In accordance with some embodiments of the present disclosure, the semiconductor device further includes a gate dielectric layer disposed between the substrate and the negative capacitance material layer, wherein the material of the gate dielectric layer is Ga₂O₃(Gd₂O₃). Moreover, the semiconductor device further includes a gate layer disposed between the gate dielectric layer and the negative capacitance layer to form a dual-gate structure.

In accordance with some embodiments of the present disclosure, the semiconductor device further includes an ion implantation layer disposed in the substrate under the gate.

In accordance with some embodiments of the present disclosure, the semiconductor device further includes a two-dimensional gas (2DEG) disposed in the substrate.

In accordance with some embodiments of the present disclosure, the aforementioned semiconductor device has agate-recessed structure.

In accordance with some embodiments of the present disclosure, a method for forming a semiconductor device for ultra-high voltage operation is provided. The method includes: forming a substrate having a normally-on channel; forming a negative capacitance layer on the substrate; and forming a drain and a source at opposite sides of the gate and electrically connected to the normally-on channel.

In accordance with some embodiments of the present disclosure, the method further includes etching the substrate, to form a trench.

In accordance with some embodiments of the present disclosure, the method further includes depositing a gate dielectric layer between the negative capacitance material layer and the substrate, and the material of the gate dielectric layer is Ga₂O₃(Gd₂O₃).

In accordance with some embodiments of the present disclosure, the method further includes forming a gate layer between the gate dielectric layer and the negative capacitance material layer.

In accordance with some embodiments of the present disclosure, the method further includes forming an ion implantation layer in the substrate under the gate.

In accordance with some embodiments of the present disclosure, the method further includes forming a two-dimensional gas (2DEG) in the substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a semiconductor device in accordance with some embodiments.

FIG. 2A illustrates a drain current-gate voltage curve diagram of a semiconductor device in accordance with some embodiments.

FIG. 2B illustrates a subthreshold swing-gate voltage curve diagram of a semiconductor device in accordance with some embodiments.

FIG. 3 illustrates a flow chart of manufacturing a semiconductor device in accordance with some embodiments.

FIGS. 4A through 4E illustrate cross-sectional views of a semiconductor device at various stages of manufacturing in accordance with some embodiments.

FIGS. 5 through 9 illustrate cross-sectional views of semiconductor devices of various types in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The invention is substantially related to a semiconductor device and a method for forming the same. More specific, the present invention is related to a semiconductor device for ultra-high voltage (UHV) operation and a method for forming the same. The semiconductor device provided by the present invention can adjust traditional semiconductor devices having a normally-on channel to change the threshold voltage from a negative value to a positive value, which further transform the operation mode of the semiconductor devices from a depletion mode (D-mode) into an enhance mode (E-mode) to lower the consumption of electricity and interference between circuits when the semiconductor devices are standby. Furthermore, the semiconductor device provided by the present invention can also reach a degree of the subthreshold swing lower than 60 mV/dec and an operation speed in nanosecond scale, which can increase the operated speed and decrease the power consumption of the semiconductor device. The semiconductor device provided by the present invention can further improve current leakage and standby power consumption.

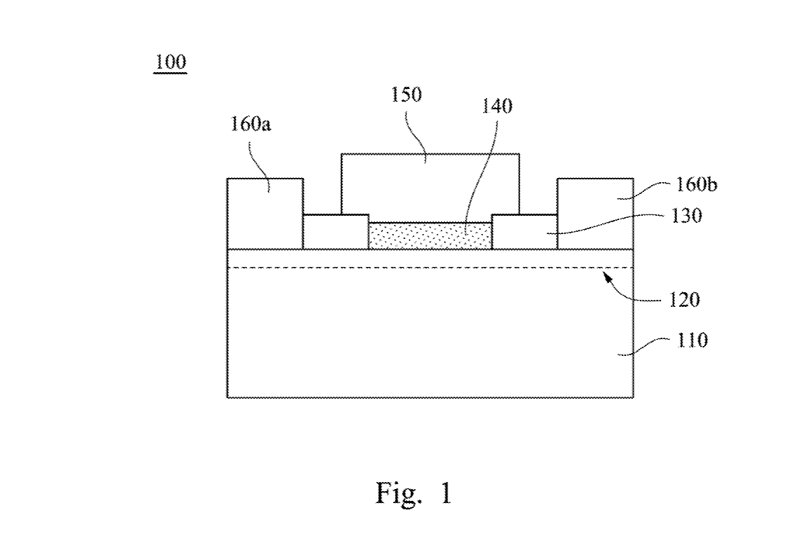

Please refer to FIG. 1, which illustrates a cross-sectional view of a type of a semiconductor device 100 in accordance with some embodiments in the present invention. As shown in FIG. 1, the semiconductor device 100 includes a substrate 110, a capping layer 130, a negative capacitance material layer 140, a gate 150, a source 160a, and a drain 160b, wherein the substrate 110 has a normally-on channel 120 and the source 160a and the drain 160b are disposed at opposite sides of the gate 150 and are electrically connected to the normally-on channel 120, it should be noticed that the normally-on channel 120 herein is an electronic channel.

The material of the aforementioned substrate 110 can be any III-V, II-VI, and IV semiconductor materials. For example, the substrate 110 includes a bulk silicon substrate. Or the substrate 110 includes an elementary semiconductor, such as silicon (Si) or germanium (Ge) in a crystalline or a poly or an amorphous structure; a compound semiconductor, such as silicon germanium (SiGe), zinc oxide (ZnO), aluminum oxide (Al₂O₃), silicon carbide (SiC), gallium arsenic (GaAs), gallium nitride (GaN), gallium phosphide (GaP), indium phosphide (InP), indium arsenide (InAs), and/or indium antimonide (InSb), cadmium sulfide (CdS), zinc sulfide (ZnS), cadmium tellurium (CdTe), aluminum gallium arsenide (AlGaAs), indium gallium phosphide (GaInP), indium gallium nitride (InGaN), indium gallium arsenic phosphorus (InGaAsP), indium gallium arsenic nitride (InAlGaN), aluminum gallium indium phosphide (AlGaInP), aluminum gallium indium arsenic (AlGaInAs), silicon germanium alloy, or any combination thereof. It should be noticed that, in some embodiments, the substrate 110 is made of Ga₂O₃. Due to the wide band gap characteristic of Ga₂O₃, the resistance to breakdown electric filed is larger. Furthermore, Ga₂O₃ substrate has potential in large-area manufacturing, and low electric resistance, which can provide larger electric current. In other embodiments, the semiconductor device includes an insulating supporting substrate disposed under the substrate 110.

The aforementioned normally-on channel 120 can be formed by doping impurities into the substrate 110. For example, the Ga₂O₃ substrate can be doped with Sn to form an electronic channel. It should be noticed that the normally-on channel represents the electronic channel between the source and the drain is open (or called “on”) rather than closed (or called “off”) although there is no voltage applied on the gate.

The aforementioned capping layer 130 is used to protect the substrate 110 from oxidation, chemical reactions or mechanical damages in the following processes. In some embodiments, the material of the capping layer 130 includes silicon oxide, silicon nitride, nickel oxide, aluminum oxide, or any combination thereof.

The aforementioned gate 150, source 160a, and drain 160b are independently selected from a group consisting of, but not limited to, silver (Ag), copper (Cu), tungsten (W), titanium (Ti), tantalum (Ta), aluminum (Al), nickel (Ni), ruthenium (Ru), palladium (Pd), platinum (Pt), Manganese (Mn), tungsten nitride (WN), titanium nitride (TiN), tantalum nitride (TaN), aluminum nitride (AlN), tungsten suicide (WSi), molybdenum nitride (MoN), nickel silicide (Ni₂Si), titanium silicide (TiSi₂), titanium aluminide (TiAl), arsenic (As) doped polycrystalline silicon, zirconium nitride (ZrN), TaC, TaCN, TaSiN, TiAlN, and any combination thereof.

The aforementioned negative capacitance material layer 140 is composed of a negative capacitance material. The term “negative capacitance material” herein represents the material having negative capacitance effect or can cause the effect in a semiconductor device. In some embodiment, the negative capacitance material can be a ferro material having negative capacitance effect. To be more specific, in the embodiment, the negative capacitance material is a high-crystallinity ferro material made of HfO₂ doped with silicon, aluminum, lanthanum, yttrium, zirconium or other elements, which includes, but not limited to, Hf₁₋ₓZrₓO, Hf_{1-y}Si_{y}O, Hf_{1-y}Al_{y}O, Hf_{1-y}Y_{y}O, Hf_{1-y}La_{y}O, or a combination thereof, wherein the x is between 0.001 and 0.999, and the y is between 0.001 and 0.1.

It should be noticed that, different from a dielectric property of a general high dielectric material, the negative capacitance material layer 140 made of the aforementioned specific material with specific range of the composition has negative capacitance effect, which can decrease the subthreshold swing and adjust the threshold voltage of the normally-on channel 120 so that the normally-on channel 120 is transformed from normally-on into normally-off, which transform the transistor characteristics of the semiconductor device from depletion mode (D-mode) into enhance mode (E-mode). Furthermore, the negative capacitance effect of the negative capacitance material layer 140 allows the semiconductor device operate in high-speed switch and modulated by high-speed pulse width modulation in nanosecond scale.

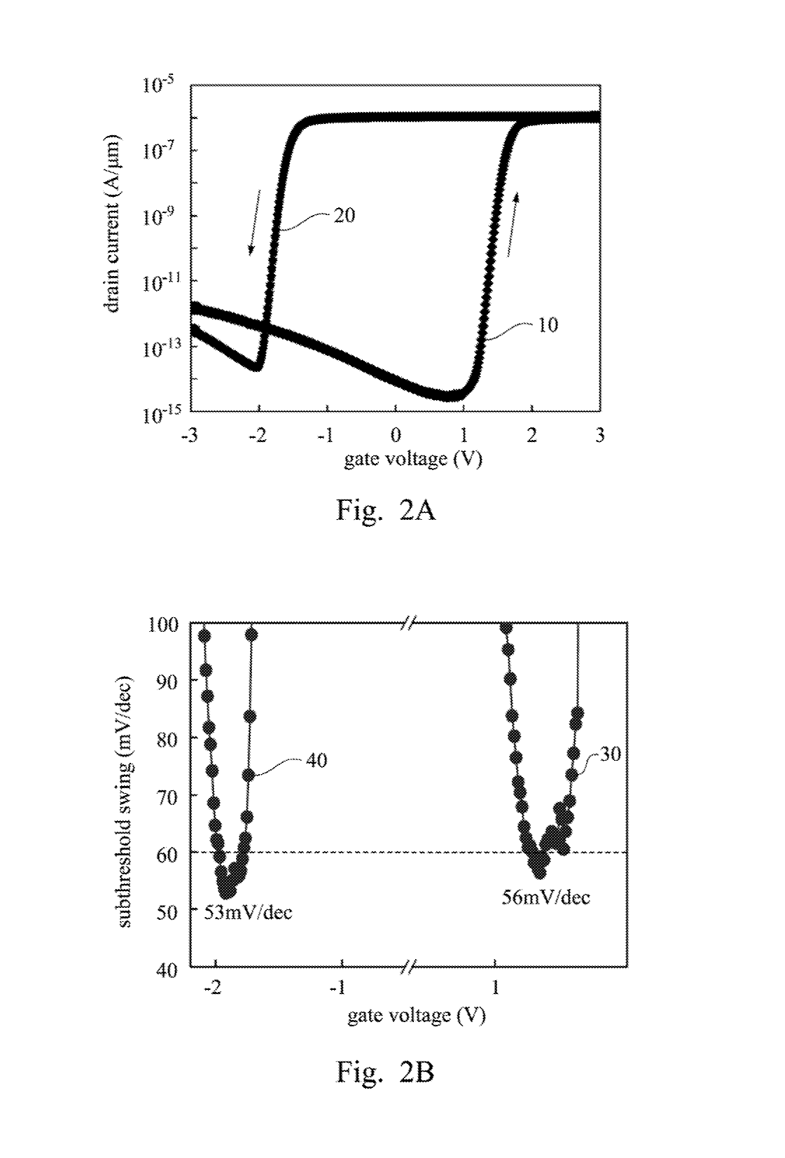

For further illustrating the aforementioned function related to the negative capacitance material layer 140 of adjusting threshold voltage and decreasing subthreshold swing, the present invention provides a specific embodiment and measuring the threshold voltage and the subthreshold swing thereof. In the specific embodiment, the substrate 110 of the semiconductor device 100 is silicon, and the negative capacitance material layer 140 is HfZrO (i.e. ration of HfO₂ to ZrO₂ is 1:1). The drain current-gate voltage curve diagram of this semiconductor device 100 is illustrated in FIG. 2A, while the subthreshold swing-gate voltage curve diagram of this semiconductor device 100 is illustrated in FIG. 2B.

Please referring to FIG. 2A, which illustrates the drain current-gate voltage curve diagram of the semiconductor device 100 under a gate voltage equals to 0.2 V in accordance with the aforementioned specific embodiment, wherein the curve 10 represents the result measured by sweeping the gate voltage from −6 V to +6 V, while the curve 20 represents the result measured by sweeping the gate voltage from +6 V to −6 V. As known from FIG. 2A, the negative capacitance material layer 140 made of HfZrO can transform the threshold voltage of the semiconductor device with silicon substrate from a negative value into a positive value (i.e. the transistor characteristics of the device is transformed from depletion mode into enhance mode).

Please referring to FIG. 2B, which illustrates the subthreshold swing-gate voltage curve diagram of the semiconductor device 100 in accordance with the aforementioned specific embodiment, wherein the curve 30 represents the result measured by sweeping the gate voltage from −6 V to +6 V, while the curve 40 represents the result measured by sweeping the gate voltage from +6 V to −6 V. As known from the FIG. 2B, the measured results of the subthreshold swing from the curves 30, 40 are 56 mV/dec and 53 mV/dec respectively, which indicate that the negative capacitance material layer 140 can effectively decrease the subthreshold swing lower than 60 mV/dec, simultaneously decreasing the off-state current and the threshold voltage, which allow the semiconductor device operate in high-speed but low power.

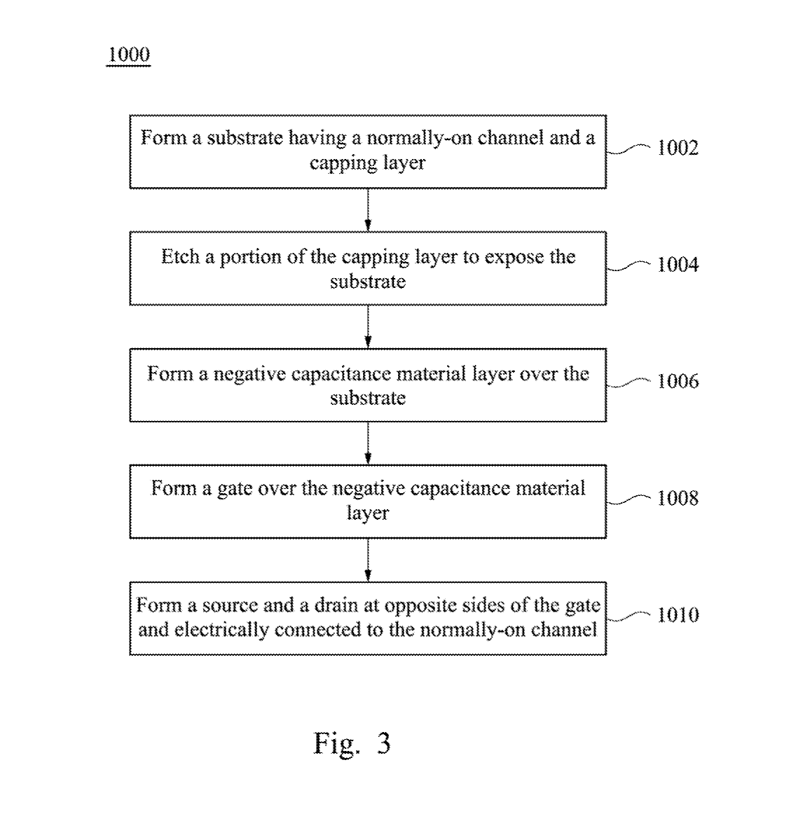

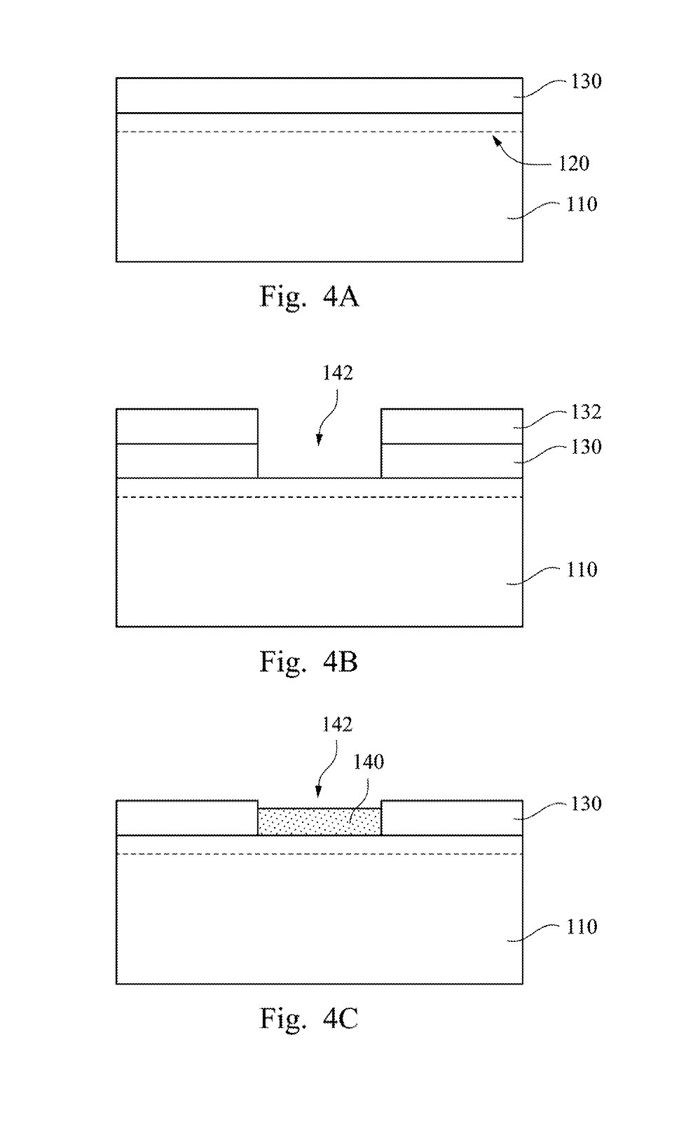

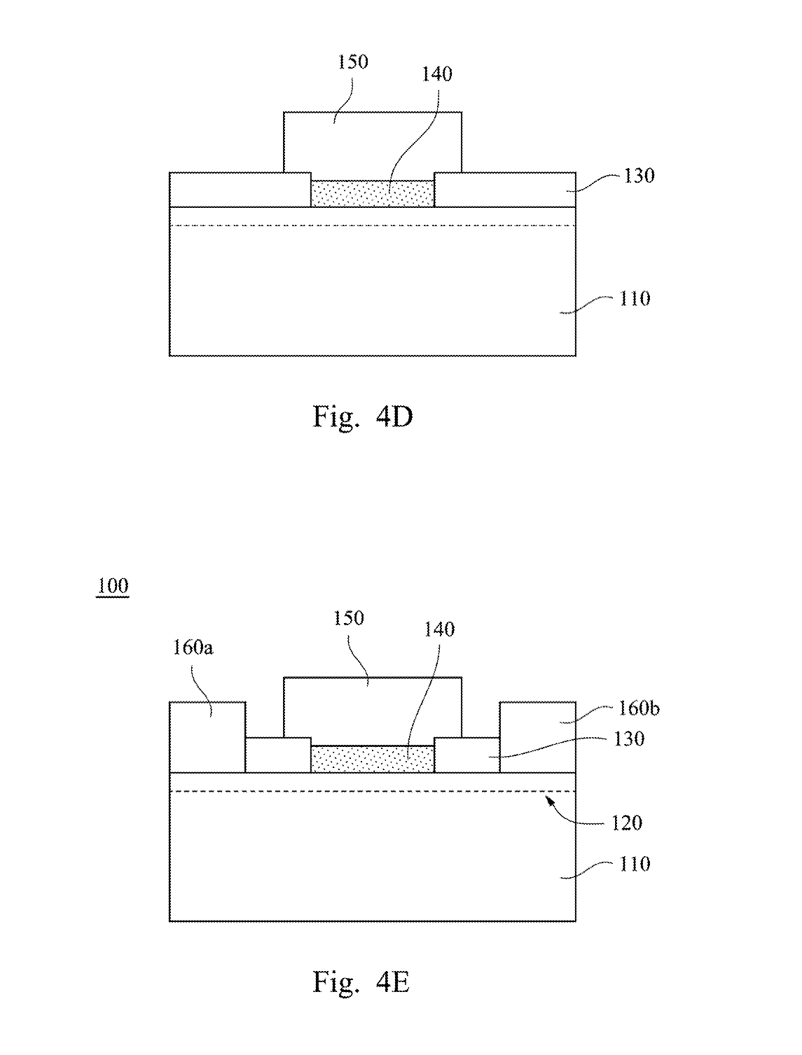

Then, please referring to FIGS. 3 and 4A through 4E, the former illustrates a flow chart of manufacturing the semiconductor device 100 of FIG. 1, while the latter illustrates cross-sectional views thereof at various stages of manufacturing. The flow chart illustrates only a relevant part of the entire manufacturing process. It is understood that additional operations may be provided before, during, and after the operations shown by FIG. 3, and some of the operations described below can be replaced or eliminated for additional embodiments of the method. The order of the operations/processes may be interchangeable.

Please refer to FIGS. 3 and 4A, the method 1000 starts from step 1002 by forming a substrate 110 having a normally-on channel 120 and a capping layer 130 over the substrate 110. In some embodiments, the substrate 110 of a single layer structure or a multiple-layer structure can be formed by metal organic vapor phase epitaxy (MOVPE) or other suitable epitaxy processes, and the normally-on channel 120 in the substrate 110 can be formed by ion implantation or other suitable doping methods. For example, electronic channel can be formed by epitaxially growing a Ga₂O₃ layer doped with Sn on a Ga₂O₃ substrate doped with Fe.

In some embodiments, the capping layer 130 can be a single layer structure or a multiple-layer structure. The capping layer 130 can be formed by chemical vapor deposition (CVD), plasma enhanced chemical vapor deposition (PECVD), physical vapor deposition (PVD), atomic layer deposition (ALD), or other deposition technologies. The materials of the substrate 110 and the capping layer 130 have been described before, which is not mentioned again.

Please refer to FIGS. 3 and 4B, the method 1000 proceeds to step 1004 by etching a portion of the capping layer 130 to expose the substrate 110. In some embodiments, a photo mask 132 having openings (not labeled) is formed by a photolithography process. Then, a portion of the capping layer 130 is removed through the openings by an etching process to expose an upper surface of the substrate 110 to form a trench 142. The aforementioned photolithography process may include forming a photo resist layer (not shown) over an upper surface of the capping layer 130, exposing the photo resist layer to form patterns, perform baking after exposure, and patterning the photo resist layer to form the photo mask 132. The aforementioned etching process may include wet-etching or dry-etching. In some embodiments, the wet etching; solution includes tetramethylammonium hydroxide (TMAH), HF/HNO₃/CH₃COOH solution, or other suitable solution. Dry etching processes include a biased plasma etching process that uses a chlorine-based chemistry, reactive-ion etching (RIE), or a combination thereof. Other dry etchant gasses include CF₄, NF₃, SF₆, or He.

Please refer to FIGS. 3 and 4C, the method 1000 proceeds to step 1006 by forming a negative capacitance material layer 140 over the substrate 110. In some embodiments, the negative capacitance material layer 140 fills into the trench 142. In some embodiments, the negative capacitance material layer 140 is formed over sidewalls of the capping layer 130 and an upper surface of the substrate 110 within the trench 142, but not fulfills the trench 142. In some embodiments, the negative capacitance material layer 140 can be formed by the aforementioned deposition processes, in some embodiments, a HfO₂ layer is deposited first, and then doped with Zr, Si, Al, Y, La or a combination thereof by an ion implantation process to form the negative capacitance material layer 140. The material of the negative capacitance material layer 140 has been described before, which is not mentioned again.

Please refer to FIGS. 3 and 4D, the method 1000 proceeds to step 1008 by forming a gate 150 over the negative capacitance material layer 140. The gate 150 can be formed by the aforementioned deposition processes. The material of the gate 150 has been described before, which is not mentioned again.

Please referring to FIGS. 3 and 4E, the method 1000 proceeds to step 1010 by forming a source 160a and a drain 160b at opposite sides of the gate 150 and are electrically connected to the normally-on channel 120. Before forming the source 150a and the drain 160b, a portion of the capping layer 130 at opposite sides of the gate 150 is etched away. Then, the source 160a and the drain 160b are formed by the aforementioned deposition processes. It should be noticed that before forming the source 160a and the drain 160b, a portion of the substrate 110 under the source 160a and the drain 160b may be doped with N-type dopants, such as P, As, Sb, Bi, Se, and Te). In other embodiments, a lightly-doped drain (LDD) may be formed in the substrate 110 under sidewalls of the gate 150 by a secondary doping process. The materials of the source 160a and the drain 160b have been described before, which is not mentioned again.

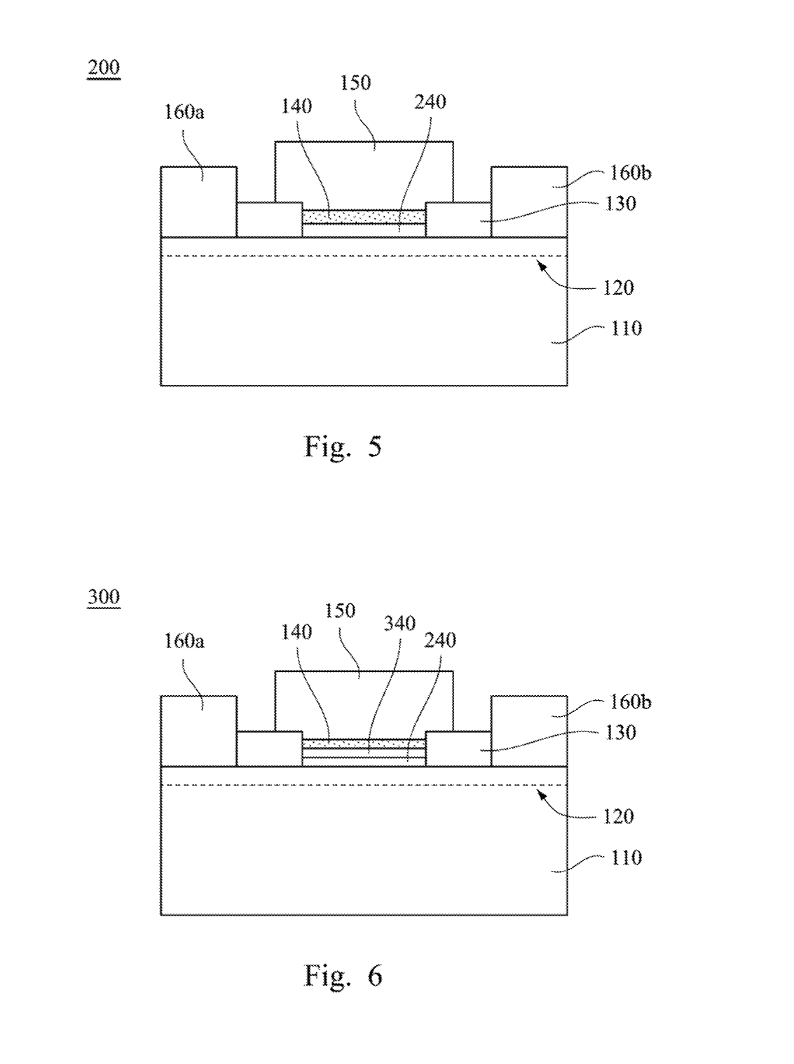

In another type of embodiments, as shown in FIG. 5, different from the semiconductor device 100, a semiconductor device 200 further includes a gate dielectric layer 240 disposed between the negative capacitance material layer 140 and the substrate 110. The material of the aforementioned gate dielectric layer 240 may be Ga₂O₃(Gd₂O₃), or called GGO, or other suitable high-K materials. It should be noticed that when Ga₂O₄(Gd₂O₃) is used as the material of the gate dielectric layer 240 and Ga₂O₃ is used as the material of the substrate 110, both the gate dielectric layer 240 and the substrate 110 are gallium-based materials, the density of interface traps (Dᵢₜ) therebetween will decrease to improve the current, leakage and standby power consumption. Therefore, the gate dielectric layer 240 and the negative capacitance material layer 140 can form a composite-function layer, not only provides functions of a dielectric layer but also adjust the threshold voltage, improves current leakage, and allows an operation under high-speed switch. The gate dielectric layer 240 may be formed over the negative capacitance material layer 140 before forming the negative capacitance material layer 140 by the aforementioned deposition processes. In some embodiments, the gate dielectric layer 240 fills into the trench 142. In other embodiments, the gate dielectric layer 240 is formed over sidewalls of the capping layer 130 and an upper surface of the substrate 110 within the trench 142.

In another type of embodiments, as shown in FIG. 6, different from the semiconductor device 200, a semiconductor device 300 further includes a gate layer 340 disposed between the gate dielectric layer 240 and the negative capacitance material layer 140. Therefore, the gate dielectric layer 240, the gate layer 340, the negative capacitance material layer 140, and the gate 150 form a dual-gate structure, which can increase effective channel length and provide the high shrinkage characteristic to allow the semiconductor device operated in high-speed semiconductor circuits. The gate layer 340 can be formed over the gate dielectric layer 240 by the aforementioned deposition processes before depositing the negative capacitance material layer 140. The material of the gate layer 340 can be polysilicon, metal gate layer, or P-type gate layer, such as, but not limited to, Cu, W, Mn, tungsten nitride (WN), tungsten silicide (WSi), titanium aluminide (TiAl), As-doped polysilicon, or a combination thereof.

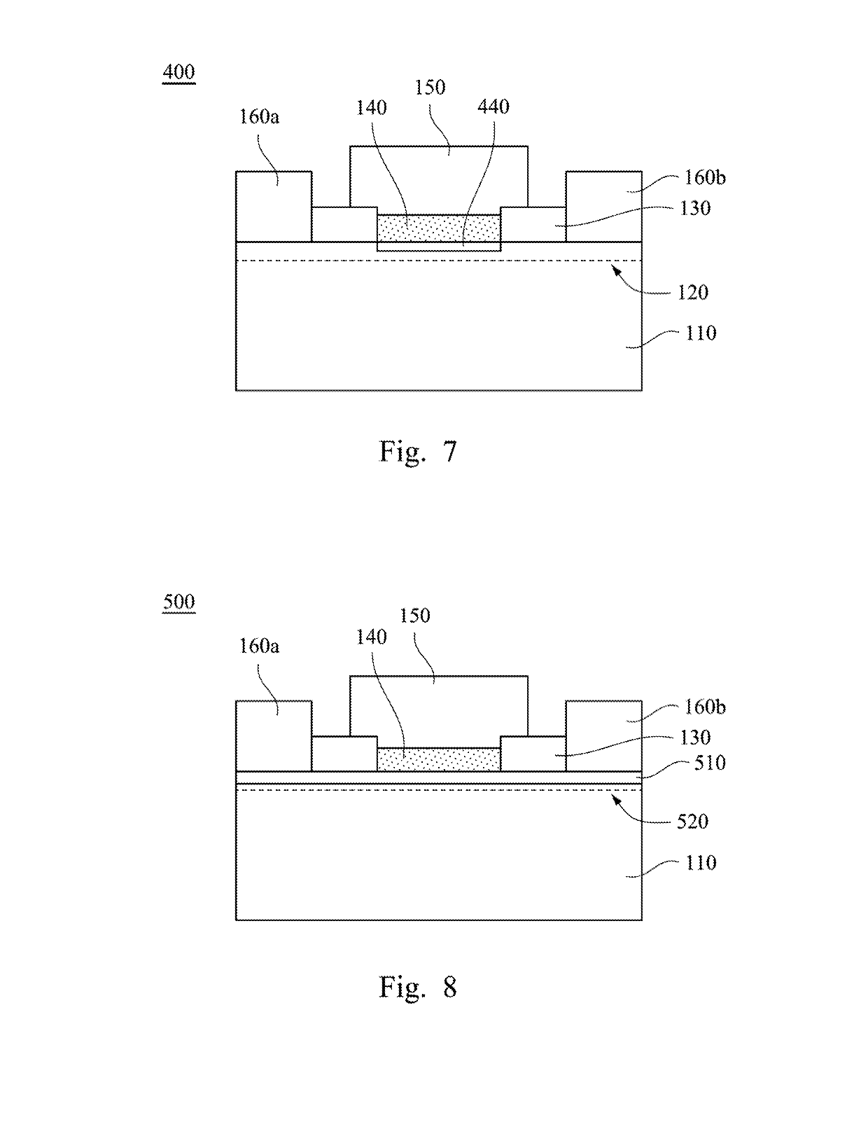

In another type of embodiments, as shown in FIG. 7, different from the semiconductor device 100, a semiconductor device 400 further includes an ion implantation layer 440 disposed in a portion of the substrate 110 under the gate 150. As shown in FIG. 7, a portion of the substrate 110 under the gate 150 may be doped with foreign elements, such as oxygen, fluorine, or a combination thereof, by any suitable processes, such as ion implantation, molecular doping, laser doping, or a combination thereof to form the ion implantation layer 440. It should be noticed that the ion implantation layer 440 can adjust charges of interfaces of the channel to adjust the threshold voltage of a transistor under the enhance mode (E-mode) precisely.

In another type of embodiments, as shown in FIG. 8, different from the semiconductor device 100, a semiconductor device 500 further includes a two-dimensional gas (2DEG) 520 disposed in the substrate 110. In some embodiments, the two-dimensional gas (2DEG) 520 is formed at an upper portion of the substrate 110 by forming a semiconductor layer 510 over the substrate 110 and properly selecting the material of the semiconductor layer 510. Thus, the two-dimensional gas (2DEG) 520 is near the interface between the substrate 110 and the semiconductor layer 510. For example, when the material of the substrate 110 is GaN, the material of the semiconductor layer 510 can be AlGaN, or when the material of the substrate 110 is Ga₂O₃, the material of the semiconductor layer 510 can be AlGa₂O₃. The semiconductor layer 510 can be grown by the aforementioned epitaxy processes. Generally, the semiconductor device 500 having the two-dimensional gas (2DEG) 520 can be used as a high electron mobility transistor (HEMT).

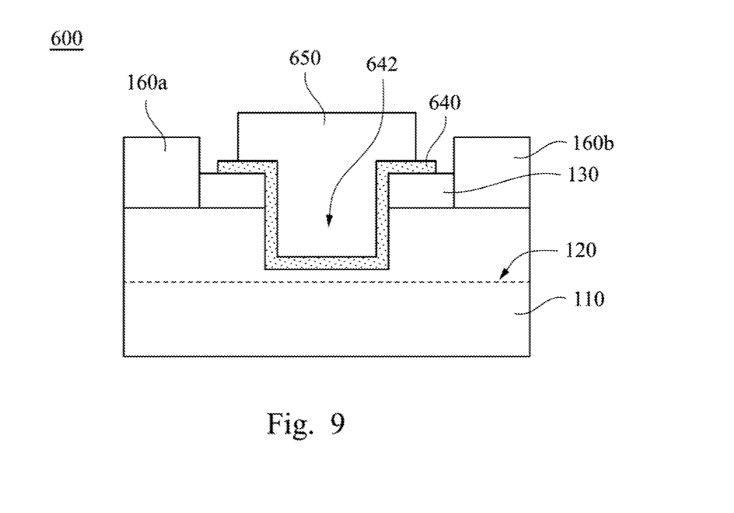

In another type of embodiments, as shown in FIG. 9, different from the semiconductor device 100, a semiconductor device 600 has a gate-recessed structure, which can decrease electron concentration of a channel, adjust the threshold voltage, transform the transistor characteristics of the semiconductor device from the depletion mode into enhance mode, or further adjust the threshold voltage under the enhance mode. As shown in FIG. 9, the gate-recessed structure represents that a gate 650 is inserted into the substrate 110, which can be formed by continue etching the exposed substrate 110 to form a trench 642 in the substrate 110 in step 1004 of the method 1000. In this way, the subsequently formed gate 650 can insert into the substrate 110 to form a gate-recessed structure. It should be noticed that, in the gate-recessed structure, the negative capacitance material layer 640 is formed at least over an upper surface and sidewalls of the substrate 110 within the trench 642 to prevent the direct contact between the gate 650 and the substrate 110. In other embodiments, the aforementioned gate dielectric layer is formed over an upper surface and sidewalls of the substrate 110 within the trench 642 first, and the negative capacitance layer is formed over a bottom and sidewalls of the trench 642. The gate-recessed structure covered with the negative capacitance layer can decrease the parasitic capacitance (C_{GS}) between metals of the gate and the source, and the parasitic capacitance (C_{GD}) between metals of the gate and the drain, to enhance operation frequency of elements for using in high-speed semiconductor circuits.

It should be noticed that the provided semiconductor devices 100, 200, 300, 400, 500, 600 for describing the present invention are not used to limit the present invention in a single technical feature. In other words, the gate dielectric layer 240, the gate layer 340, the ion implantation layer 440, the semiconductor layer 510, the two-dimensional gas (2DEG) 520, and the gate-recessed structure of the semiconductor devices 100, 200, 300, 400, 500, 600 can be added into the semiconductor device 100 in any combination instead of being restricted into any of the aforementioned single semiconductor device.

Given the above, each embodiment in the present invention has advantages over the existed semiconductor device for ultra-high voltage operation and manufacturing process for forming the same, and the advantages are summarized as below. The negative capacitance material layer having negative capacitance effect and composed of the specific ferro material can dramatically adjust the threshold voltage, transforming the transistor characteristics of the semiconductor device from normally-on depletion mode (D-mode) into normally-off enhance mode (E-mode), so that the electric current between source and drain can be avoided when no voltage is applied on the gate, which makes the semiconductor device being at a close state. The present invention further forms gate dielectric layer of Ga₂O₃(Gd₂O₃) between the negative capacitance material layer and the substrate. When the material of the substrate is Ga₂O₃ or GaN, both the gate dielectric layer and the substrate are gallium-based materials, the gate current leakage and standby power consumption of the semiconductor device can be improved. Furthermore, the present invention further forms a gate layer between the aforementioned negative capacitance material layer and the gate dielectric layer to form a dual-gate structure, which can adjust electron concentration of the channel and improve the standby power consumption of the semiconductor device for applying in high-speed semiconductor circuits. The present invention further dopes foreign elements into a portion of the substrate under the gate to adjust charges, of the interfaces of the channel to adjust the threshold voltage under the enhance mode (E-mode). The present invention further applies the gate-recessed structure in the aforementioned semiconductor devices to further adjust the threshold voltage for improving the standby power consumption of the semiconductor device.

In accordance with some embodiments of the present disclosure, a semiconductor device for ultra-high voltage operation is provided. The semiconductor device includes a substrate having a normally-on channel, a negative capacitance material layer, a gate, a drain, and a source, wherein the negative capacitance layer is disposed on the substrate, the gate is disposed on the negative capacitance material layer, and the drain and the source are disposed on opposite of the gate and are electrically connected to the normally-on channel.

In accordance with some embodiments of the present disclosure, a method for forming a semiconductor device for ultra-high voltage operation is provided. The method includes: forming a substrate having a normally-on channel; forming a negative capacitance layer on the substrate; and forming a drain and a source at opposite sides of the gate and electrically connected to the normally-on channel.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing front the spirit and scope of the present disclosure.

1. A semiconductor device for ultra-high voltage operation, comprising:
a substrate comprising a normally-on channel;
a negative capacitance material layer disposed over the substrate, the material of the negative capacitance material layer being selected from the group consisting of Hf₁₋ₓZrₓO, Hf_{1-y}Si_{y}O, Hf_{1-y}Al_{y}O, Hf_{1-y}Y_{y}O, Hf_{1-y}La_{y}O, and a combination thereof, wherein the x is between 0.001 and 0.999 and the y is between 0.001 and 0.1;
a gate disposed over the negative capacitance material layer; and
a drain and a source disposed at opposite sides of the gate and electrically connected to the normally-on channel.

2. (canceled)

3. The semiconductor device of claim 1, wherein the material of the substrate comprises Ga₂O₃, GaN, InAlGaN, AlGaInP, AlGaInAs, ZnO, SiC, or a combination thereof.

4. The semiconductor device of claim 1, further comprising a gate dielectric layer disposed between the substrate and the negative capacitance material layer, and the material of the gate dielectric layer is Ga₂O₃(Gd₂O₃).

5. The semiconductor device of claim 1, further comprising a gate layer disposed between the negative capacitance layer and the gate dielectric layer.

6. The semiconductor device of claim 1, further comprising an ion implantation layer disposed in the substrate under the gate.

7. The semiconductor device of claim 1, further comprising a two-dimensional gas (2DEG) disposed in the substrate.

8. The semiconductor device of claim 1, wherein the substrate comprises a trench and the negative capacitance material layer is filled into the trench.

9. The semiconductor device of claim 8, further comprising a gate dielectric layer disposed between the substrate and the negative capacitance material layer, and the material of the gate dielectric layer is Ga₂O₃(Gd₂O₃).

10. The semiconductor device of claim 9, further comprising a gate layer disposed between the negative capacitance layer and the gate dielectric layer.

11. The semiconductor device of claim 8, further comprising an ion implantation layer disposed in the substrate under the gate.

12. The semiconductor device of claim 8, further comprising a two-dimensional gas (2DEG) disposed in the substrate.

13. The semiconductor device of claim 12, further comprising a semiconductor layer disposed over the substrate to form the 2DEG, and the material of the semiconductor layer is AlGa₂O₃ or AlGaN.

14-20. (canceled)
